(19) United States
(12) Patent Application Publication
(10) Pub. No.: US 2013/0276883 A1
(43) Pub. Date: Oct. 24, 2013

(54) ROTATABLE MOUNTING SYSTEM

(71) Applicants: Hakim F. Belaidi, Durham, NH (US); Joseph R. Deluca, Jackson, NJ (US); Ronald A. Decker, Turnersville, NJ (US); Anthony L. Russo, Old Bridge, NJ (US); Kenneth W. Fasanella, Ocean Township, NJ (US); Bruce Modick, Boonton, NJ (US)

(72) Inventors: Hakim F. Belaidi, Durham, NH (US); Joseph R. Deluca, Jackson, NJ (US); Ronald A. Decker, Turnersville, NJ (US); Anthony L. Russo, Old Bridge, NJ (US); Kenneth W. Fasanella, Ocean Township, NJ (US); Bruce Modick, Boonton, NJ (US)

(73) Assignee: PETRA SOLAR, INC., South Plainfield, NJ (US)

(21) Appl. No.: 13/819,057

(22) PCT Filed: Aug. 22, 2011
(86) PCT No.: PCT/US11/48608

§ 371 Date: Jul. 11, 2013

Related U.S. Application Data
(60) Provisional application No. 61/402,268, filed on Aug. 26, 2010.

(51) Int. Cl. H01L 31/042

(52) U.S. Cl. CPC H01L 31/0422
USPC 136/259

(57) ABSTRACT

A rotatable assembly for supporting a fixture from a structure may be provided. The rotatable assembly may comprise a mounting bracket and a support arm rotatably attached to the mounting bracket. The support arm may have a connection point for receiving the fixture.

### CROSS-REFERENCE TO RELATED APPLICATIONS

This application is being filed on 22 Aug. 2011, as a PCT International Patent application in the name of Petra Solar, Inc., a U.S. national corporation, applicant for the designation of all countries except the U.S., and, Hakim F. Belaidi, a citizen of the U.S., Joseph R. DeLuca, a citizen of the U.S., Ronald A. Decker, a citizen of the U.S., Anthony L. Russo, a citizen of the U.S., Kenneth W. Fasanella, a citizen of the U.S., and Bruce Modick, a citizen of the U.S., applicants for the designation of the U.S. only, and claims priority to U.S. patent application Ser. No. 61/402,268 filed on 24 Aug. 2010, the disclosure of which is incorporated herein by reference in its entirety.

### BACKGROUND

Utility poles have various items, such as lights, that may be attached to them. The items are attached in a static manner. When a worker needs to perform maintenance or otherwise access an item attached to the utility pole, another item may obstruct access.

### SUMMARY

A rotatable assembly for supporting a fixture from a structure may be provided. The rotatable assembly may comprise a mounting bracket and a support arm rotatably attached to the mounting bracket. The support arm may have a connection point for receiving the fixture.

Both the foregoing general description and the following detailed description are examples and should not be considered restrictive of the scope of the invention, as described and claimed. Further, features and/or variations may be provided in addition to those set forth herein. For example, embodiments of the invention may be directed to various combinations and sub-combinations of the features described in the detailed description.

### BRIEF DESCRIPTION OF THE DRAWINGS

The accompanying drawings, which are incorporated in and constitute a part of this disclosure, illustrate various embodiments of the present invention. In the drawings:

FIG. 1 shows an operating environment for a rotatable assembly for supporting a fixture from a structure;

FIG. 2 shows a rotatable assembly for supporting a fixture from a structure;

FIG. 3 shows a rotatable assembly for supporting a fixture from a structure;

FIG. 4 shows the rotatable assembly in FIG. 3 in a second position;

FIG. 5 shows locking mechanisms;

FIG. 6 shows a rotatable assembly for supporting a fixture from a structure;

FIG. 7 shows the rotatable assembly in FIG. 6;

FIG. 8 shows a rotatable assembly for supporting a fixture from a structure; and

FIGS. 9A and 9B show a fixed assembly.

### DESCRIPTION

The following detailed description refers to the accompanying drawings. Wherever possible, the same reference numbers are used in the drawings and the following description to refer to the same or similar elements. While embodiments of the invention may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the invention.

Consistent with embodiments of the invention, a rotatable assembly may be provided. With embodiments of the invention, the rotatable assembly may comprise a mounting bracket and a support arm. The support arm may be rotatably attached to the mounting bracket. The support arm may comprise a connection point for receiving a fixture.

Embodiments of the invention may allow workers to rotate an assembly (e.g., a rotatable apparatus) to gain easier access to structures (e.g., utility poles) for repairs and maintenance. For instance, embodiments of the invention may include swivels and locking mechanisms to allow movement of the rotatable apparatus and improved safety for workers.

Embodiments of the invention may allow items, solar panels for example, to be located in a common pole space (e.g., 4 inches below a wire or cable (vertical) and 12 inches from (horizontal) the pole). For example, panels may be equipped with a service release that may be temporarily repositioned to provide access to communication attachments.

A rotatable support arm may allow a panel to be temporarily moved around the pole to provide access to communication facilities. Embodiments of the invention may also allow for rotation of the panel without requiring special tools. For example, the panel may be able to be locked in a temporary position while a worker performs utility work. Embodiments of the invention may allow for clearance below the communication cable or other devices and equipment attached to the pole.

The rotating mounting brackets may be used where it may be necessary to temporarily reposition panels in order to, for example, provide access to meet space requirements required by electrical codes and to provide for a safe distance from high voltage lines. These clearances may allow easy access to the pole and any attachments using a bucket, ladder, or while a worker is climbing the pole.

The aforementioned solar panels may include a photovoltaic (PV) assembly. The PV assembly may comprise at least one photovoltaic panel that may be capable of converting solar energy to Direct Current (DC) electricity. An inverter module, may be capable of converting the DC electricity to Alternating Current (AC) electricity. These items may be attached to a rotatable support arm that may be attached to the pole.

Included in the rotatable support arm may be a mechanism (e.g., a swivel joint) to rotate the PV assembly at various angles (e.g., from 10 degrees to 90 degrees) relative the support arm or the pole. The support arm may comprise a connection point for mounting and latching the PV panel to the support arm. The PV assembly may further comprise an alignment mechanism that may facilitate locking the PV assembly.

Upon work completion, the aforementioned locking may be undone and the PV assembly may be repositioned to its initial position or any other position. The alignment and locking mechanism may comprise a set of integral knobs, alignment pins, and/or positive locking hardware. The support arm may be installed at any location on the pole. The locking mechanism may have a swivel action allowing the PV panel or the support arm to be repositioned to either side of the pole or the rear part of the poles, locked, and repositioned.

Embodiments of the invention may allow the PV panel and support arm to be installed at any location on the pole. The rotatable connection between a mounting bracket that may be attached to the pole and the support arm may allow the support arm to be folded down along the pole's length.

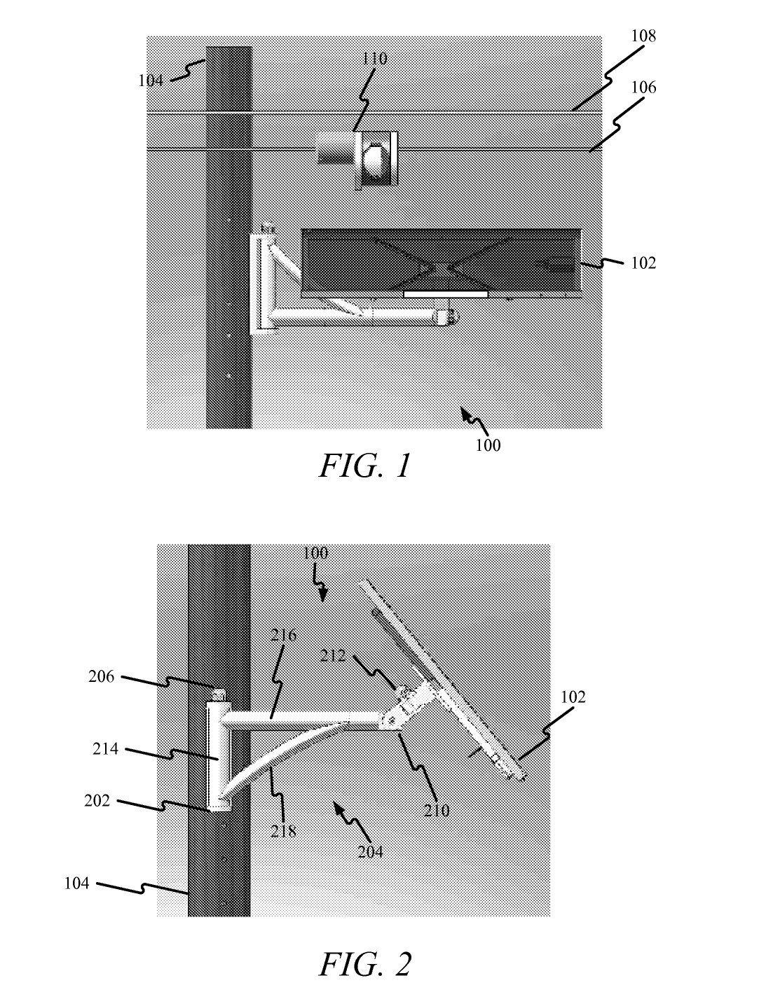

FIG. 1 shows an operating environment for a first rotatable assembly 100 for supporting a first fixture 102 from a structure 104. As described above, first fixture 102 may comprise a PV cell or other electrical components. Structure 104 may comprise a utility pole. First rotatable assembly 100 may allow first fixture 102 to be repositioned so a worker may have unimpeded access to a first wire 106 and/or a second wire 108. For example, a worker may need to perform some lashing operations on first wire 106 using a cable lasher 110. First rotatable assembly 100 may allow first fixture 102 to be moved so the worker has easy access to first wire 106 via cable lasher 110.

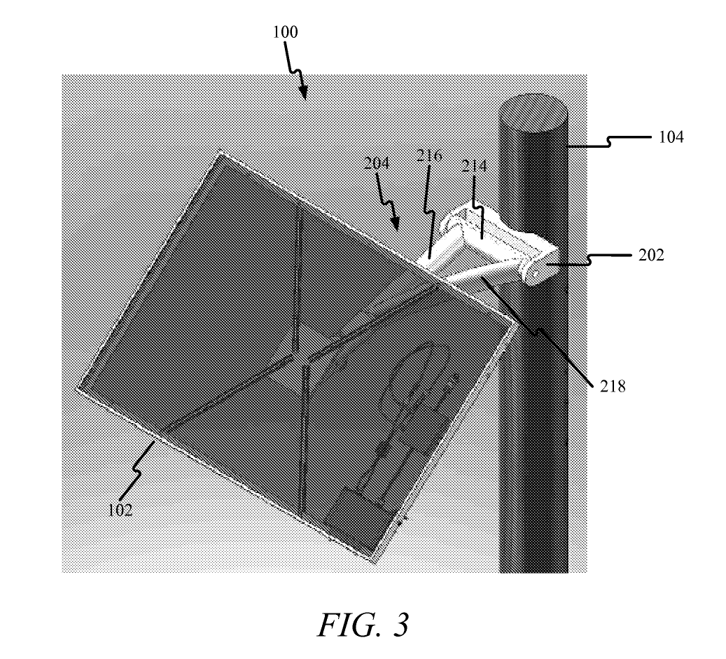

FIG. 2 shows first rotatable assembly 100 in greater detail. First rotatable assembly 100 may comprises a first mounting bracket 202 that may be connected to structure 104. First mounting bracket 202 may be connected to structure 104 in a vertical manner. As shown in FIG. 2, first rotatable assembly 100 may comprise a first support arm 204 that may be connected to first mounting bracket 202. First mounting bracket 202 may comprise a first locking mechanism 206 that may facilitate locking first support arm 204 in a fixed position relative to structure 104.

First support arm 204 may also comprise a first connection point 210 to allow first fixture 102 to be repositioned and secured in a fixed position relative to first support arm 204. First support arm 204 may also comprise a second connection point 212. Second connection point 212 may allow for first fixture 102 to have greater freedom of movement. For example, as shown in FIG. 2, first connection point 210 may allow first fixture 102 to pivot clockwise or counter-clockwise relative to first support arm 204 and in the plane of the page. Second connection point 212 may allow first fixture 102 to pivot into and out of the plane of the page.

First support arm 204 may comprise a first vertical member 214, a first horizontal member 216, and a first cross member 218. First vertical member 214 may be rotatably attached to first mounting bracket 202 and having an upper end and a lower end. First horizontal member 216 may comprise a near end and a far end and the near end may be attached to first vertical member 214 proximate the upper end. First horizontal member 216 may be oriented perpendicular to first vertical member 214. First cross member 218 may comprise a first end and a second end. The first end may be attached first vertical member 214 proximate the lower end and the second end may be attached to first horizontal member 216 proximate the far end. First cross member 218 may be straight or curved. First vertical member 214, first horizontal member 216, and first cross member 218 may be connected to form a substantially triangular shape.

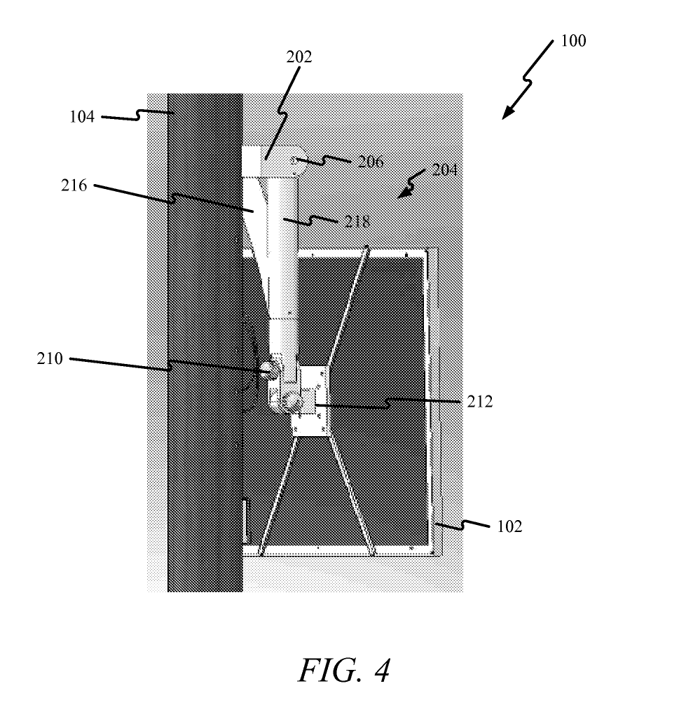

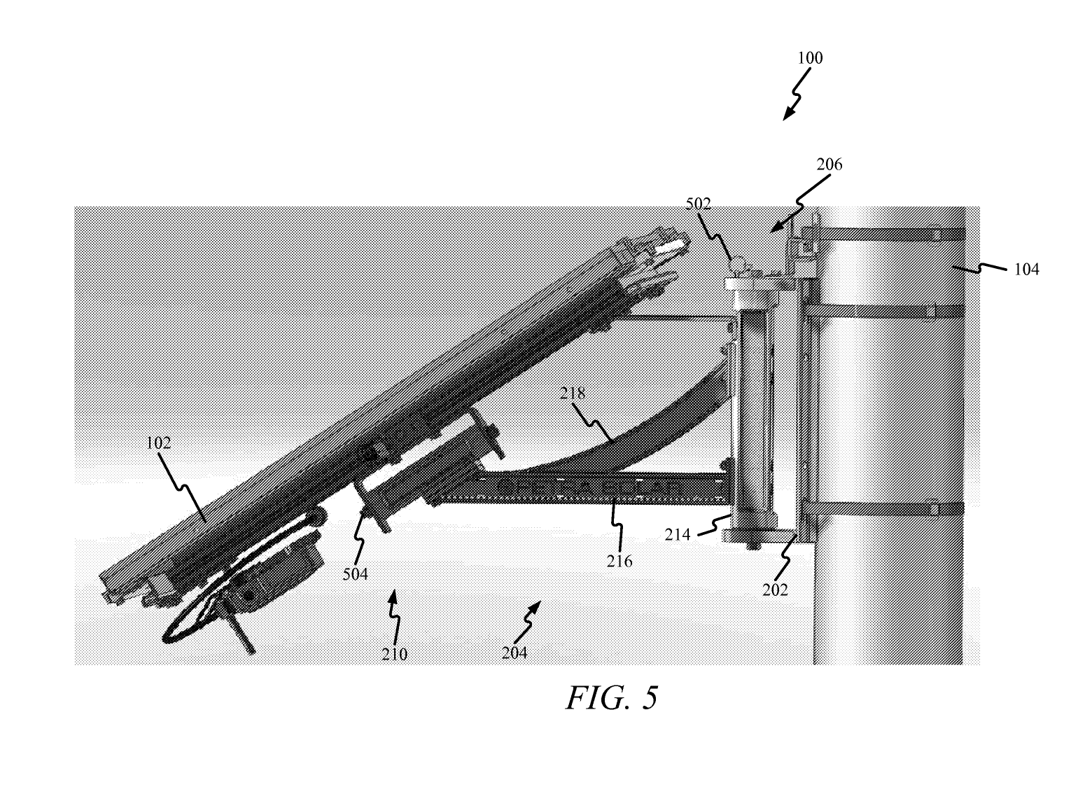

FIG. 3 shows first rotatable assembly 100 attached to structure 104 in a first position (i.e., an extended position). First mounting bracket 202 and first support arm 204 may be mounted perpendicular to structure 104. Embodiments of the invention that comprise first rotatable assembly 100 attached perpendicularly to structure 104. This may cause first mounting bracket 202 to have a decreased footprint on structure 104. The footprint may be defined as the surface area of structure 104 that is covered by first mounting bracket 202. FIG. 4 shows first rotatable assembly 100 in a second position (e.g., in a retracted or folded down position).

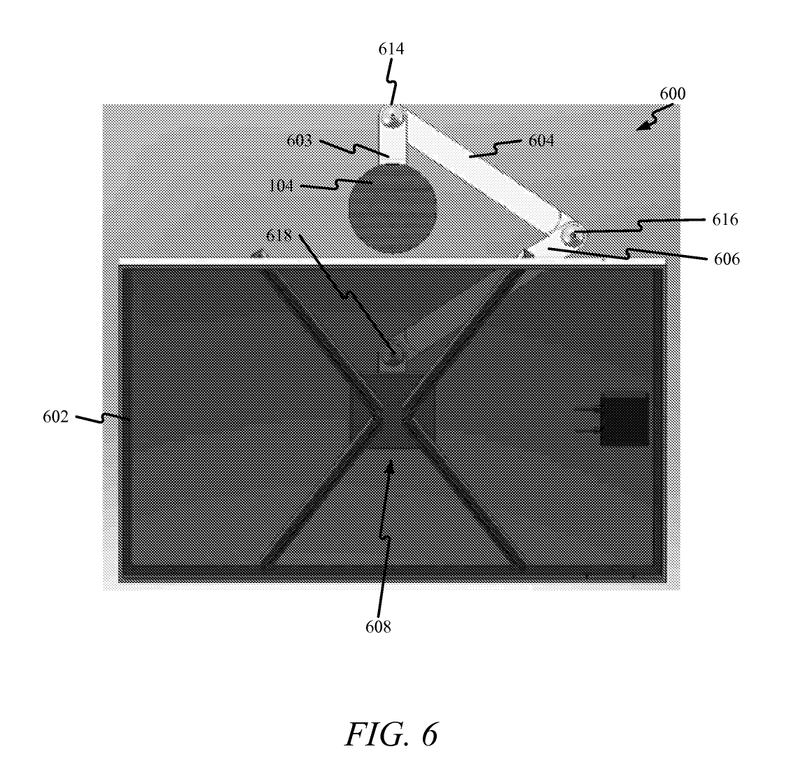

FIG. 5 shows first locking mechanism 206 and first connection point 210 in greater detail. Embodiments of the invention may include first locking mechanism 206 comprising a first knob 502. First knob 502 may be connected to, for example, a screw or threaded rod, that may allow a user to tighten first knob 502 to help secure first support arm 204 in a fixed position. First knob 502 may require the use of tools, either standard or specialized, to properly secure it in position. Specialized tools may be utilized to prevent unauthorized persons from repositioning or tampering with first support arm 204. In addition, embodiments of the invention may not require tool use and a worker may be able to secure first support arm 204 using the worker's hands.

First connection point 210 may comprise a second knob 504. Second knob 504 may be connected to, for example, a screw or threaded rod, that may allow a user to tighten second knob 504 to help secure first fixture 102 in a fixed position. Second knob 504 may require the use of tools, either standard or specialized, to properly secure it in position. Specialized tools may be utilized to prevent unauthorized persons from repositioning or tampering with first fixture 102. In addition, embodiments of the invention may not require the use of tools and a worker may be able to secure it using only his hands. While FIG. 5 shows only one swivel joint (e.g., first connection point 210), embodiments of the invention may utilize more than on swivel joint (e.g., second connection point 212 in FIG. 4).

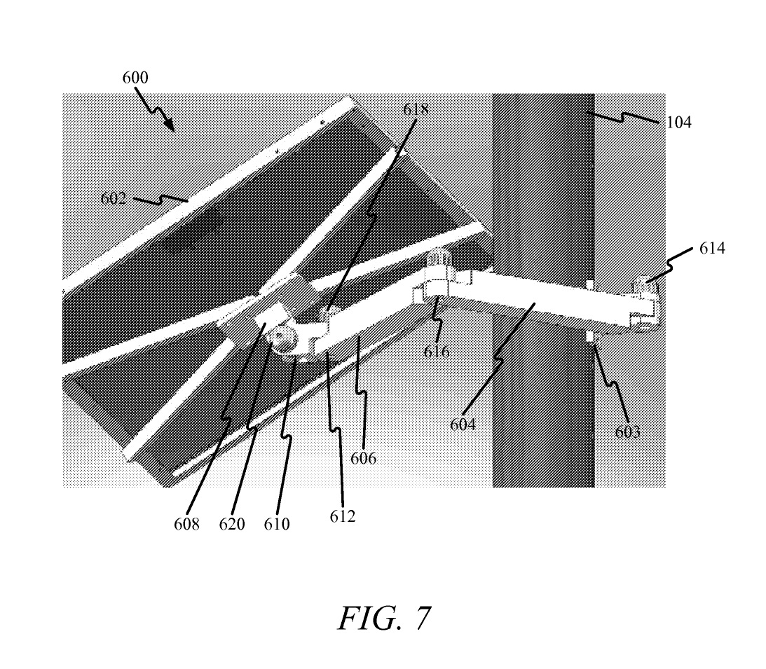

FIG. 6 shows a second rotatable assembly 600 for supporting second fixture 602 from structure 104. Second rotatable assembly 600 may comprise a second mounting bracket 603, a first section 604, a second section, 606, and a second connection point 608. A second mounting bracket 603 may be connected to structure 104. First section 604 may be connected to second mounting bracket 603 such that first section 604 is able to rotate about structure 104. Second section 606 may be connected to first section 604 such that second section 606 is able to rotate about first section 604 and structure 104. While FIG. 6 only shows second rotatable assembly 600 having two sections, embodiments of the invention may comprise any number of sections.

Embodiments of the invention that have multiple sections that may allow first fixture 102 to be positioned in any position around structure 104. For example, second fixture 602 may be a platform. Utilizing second rotatable assembly 600, a worker may be able to position first fixture 102 on an opposite side of structure 104. This may allow the worker to gain better access to equipment that needs to be serviced, provide the worker with a platform with which he can stand to work, or provide the worker with a platform to hold tools.

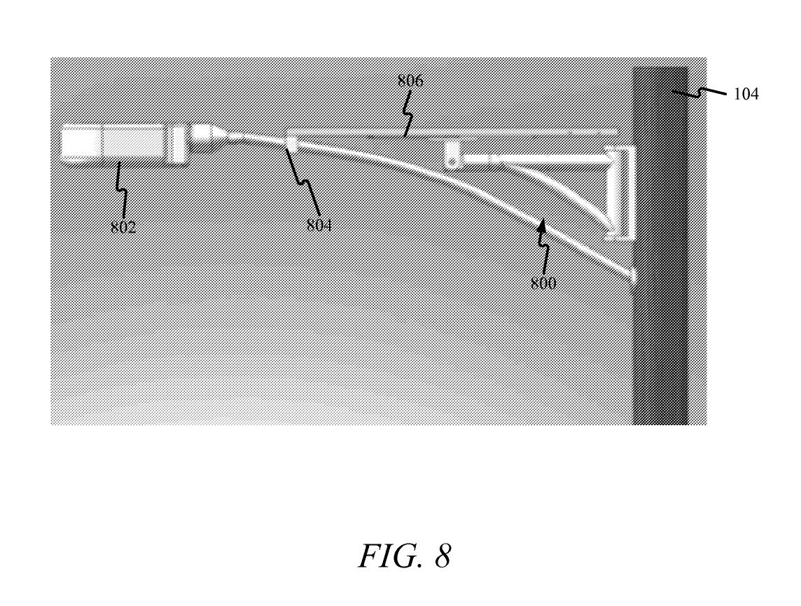

FIG. 7 shows second rotatable assembly 600. First section 604 may be connected to second mounting bracket 603. A joint between first section 604 and second mounting bracket 603 may comprise a second locking mechanism 614 configured to lock first section 604 in a fixed position relative to second mounting bracket 603. First section 604 may be connected to second section 606. A joint between first section 604 and second section 606 may comprise a third locking mechanism 616 configured to lock second section 606 in a fixed position relative to first section 604. Second section 606 may be connected to second connection point 608. A joint between second section 606 and second connection point 608 may comprise a fourth locking mechanism 618 configured to lock second connection point 608 in a fixed position relative to second section 606. In addition, second connection point 608 may comprise pivot points (e.g., a first swivel joint 610 and a second swivel joint 612) that may allow second fixture 602 greater freedom of movement. Furthermore, second locking mechanism 614, third locking mechanism 616, and fourth locking mechanism 618 may comprise multiple pivoting joints to allow first section 604 and second section 606 greater freedom of movement.

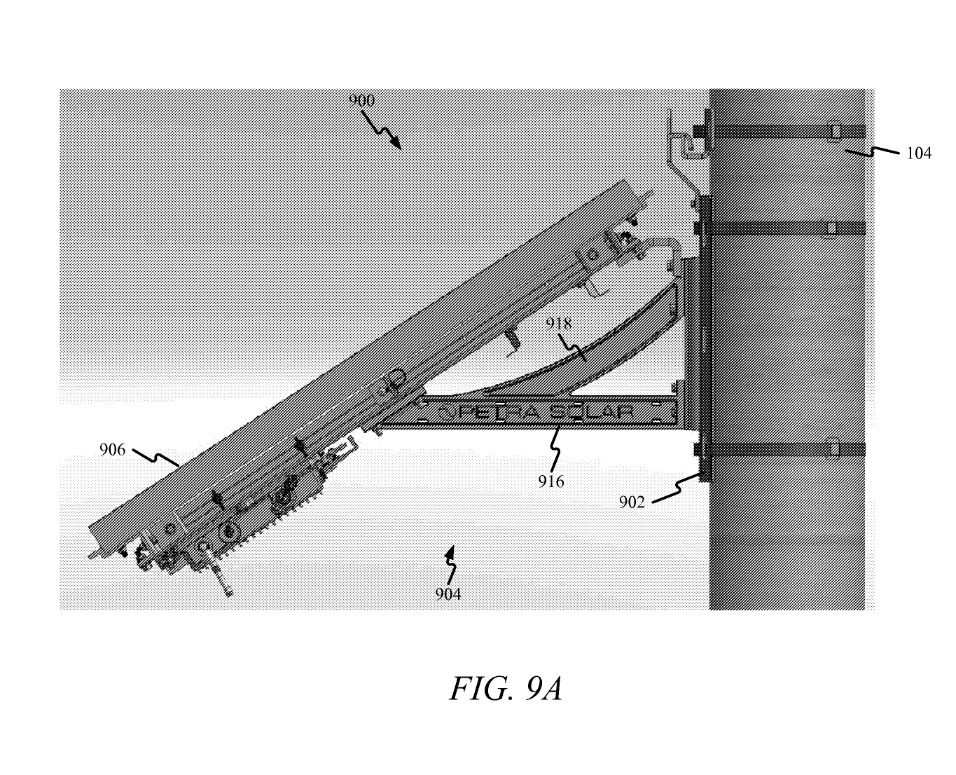

FIG. 8 shows a third rotatable assembly 800 for supporting a fixed fixture 802 from structure 104. As shown in FIG. 8, fixed fixture 802 (e.g., a street light) may be attached to structure 104 (e.g., a utility pole). While performing maintenance on fixed fixture 802, a worker may wish to move a movable fixture 806 in order to gain easier access to fixed fixture 802. To reposition movable fixture 806, the worker may need to disengage a latch 804. Latch 804 may secure movable fixture 806 in a fixed position relative to fixed fixture 802. After the worker has disengaged latch 804, he may rotate third rotatable assembly 800 to either side of structure 104 in order to gain easier access to fixed fixture 802.

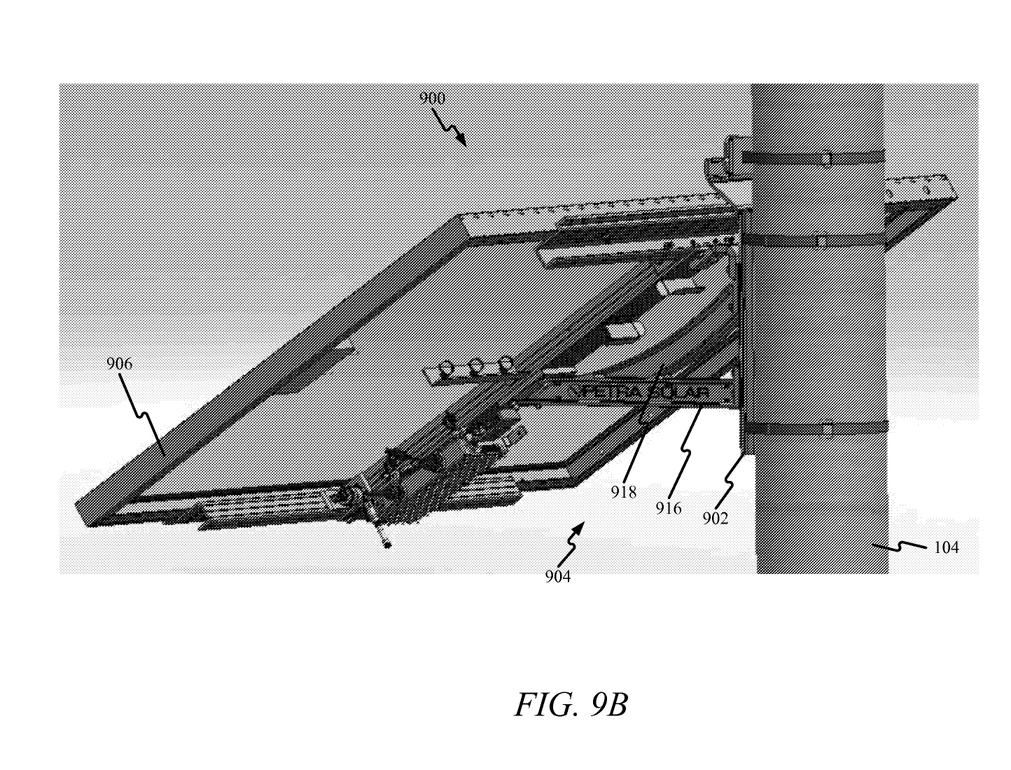

FIGS. 9A and 9B show a fixed assembly 900. Fixed assembly 900 may comprise a third mounting bracket 902, a second support arm 904, and a third fixture 906. Third mounting bracket 902 and second support arm 904 may be mounted perpendicular to structure 104.

Second support arm 904 may comprise a second horizontal member 916 and a second cross member 918. Second support arm 904 may be attached to third mounting bracket 902. Second horizontal member 916 may comprise a near end and a far end. The near end may be attached to third mounting bracket 902. Second horizontal member 916 may be oriented perpendicular to third mounting bracket 902. Second cross member 918 may comprise a first end and a second end.

The first end may be attached third mounting bracket 902 proximate the lower end The second end may be attached to second horizontal member 916 proximate the far end. Second cross member 918 may be straight or curved. Third mounting bracket 902, second horizontal member 916, and second cross member 918 may be connected to form a substantially triangular shape.

While certain embodiments of the invention have been described, other embodiments may exist. While the specification includes examples, the invention's scope is indicated by the following claims. Furthermore, while the specification has been described in language specific to structural features and/or methodological acts, the claims are not limited to the features or acts described above. Rather, the specific features and acts described above are disclosed as examples for embodiments of the invention.

What is claimed is:

1. A rotatable apparatus comprising:
a mounting bracket; and
a support arm rotatably attached to the mounting bracket, the support arm having a connection point for receiving a fixture.

2. The rotatable apparatus of claim 1, further comprising a locking mechanism operable to lock the support arm in a fixed position.

3. The rotatable apparatus of claim 1, wherein the mounting bracket is configured to be attached to a structure in a vertical orientation.

4. The rotatable apparatus of claim 1, wherein the mounting bracket is configured to be attached to a structure in a horizontal orientation.

5. The rotatable apparatus of claim 1, wherein the support arm has a substantially triangular shape.

6. The rotatable apparatus of claim 1, wherein the support arm comprises a first section pivotably connected to a second section and a section arm pivotably connected to the second section.

7. The rotatable apparatus of claim 6, wherein the first section, the second section, and the third section are configured to allow the fixture to be rotated at least 270 degrees.

8. The rotatable apparatus of claim 1, wherein the fixture comprises a photovoltaic cell.

9. The rotatable apparatus of claim 1, wherein the support arm comprises plastic I-beams.

10. The rotatable apparatus of claim 1, wherein the support arm comprises:
a vertical member rotatably attached to the mounting bracket and having an upper end and a lower end;
a horizontal member having a near end and a far end, the near end being attached to the vertical member proximate the upper end, the horizontal member being oriented perpendicular to the vertical member; and
a cross member having a first end and a second end, the first end attached to the vertical member proximate the lower end and the second end attached to the horizontal member proximate the far end.

11. The rotatable apparatus of claim 1, wherein the connection point comprises a lockable swivel joint.

12. A rotatable apparatus comprising:
a mounting bracket having a first mating surface contoured to complement a second mating surface of a structure; and
a support arm rotatably attached to the mounting bracket, the support arm comprising:
a first section,
a second section being rotatably attached to the first section, and
an end section being rotatably attached to the second section and comprising a connection point for receiving a fixture.

13. The rotatable apparatus of claim 12, wherein the first section and the second section are configured to lock a fixed position relative to each other.

14. The rotatable apparatus of claim 12, wherein the connection point comprises a lockable swivel joint.

15. The rotatable apparatus of claim 12, wherein the fixture comprises a photovoltaic cell.

16. The rotatable apparatus of claim 12, wherein the fixture comprises a utility box.

17. The rotatable apparatus of claim 12, wherein the first section and the second section are configured to rotate the connection point at least 180 degrees.

18. The rotatable apparatus of claim 12, wherein the structure comprises a utility pole.

19. A rotatable apparatus comprising:
a mounting bracket attached to a pole, the mounting bracket comprising a locking mechanism; and
a substantially triangular support arm being connected to the mounting bracket and configured to be locked in a first fixed position relative to the mounting bracket, the substantially triangular support arm comprising a connection point being connected to a photovoltaic cell, the connection point configured to lock the photovoltaic cell in a fixed position relative to the substantially triangular support arm.

20. The rotatable apparatus of claim 19, wherein the substantially triangular support arm comprises plastic I-beams.
